(19) United States
(12) Patent Application Publication
(10) Pub. No.: US 2023/0147331 A1
(43) Pub. Date: May 11, 2023

(54) ENERGY STORAGE SYSTEM

(71) Applicant: LG ELECTRONICS INC., Seoul (KR)

(72) Inventors: Taejun KIM, Seoul (KR); Byeongsu KIM, Seoul (KR); Kijung RYU, Seoul (KR)

(21) Appl. No.: 17/947,307

(22) Filed: Sep. 19, 2022

(30) Foreign Application Priority Data
Nov. 8, 2021 (KR) 1020210152588

(51) Int. Cl. H01M 10/6568; H01M 10/613; H01M 10/6551; H05K 7/20

(52) U.S. Cl. CPC H01M 10/6568; H01M 10/613; H01M 10/6551; H05K 7/2089; H05K 7/20154; H05K 7/20272

(57) ABSTRACT

An energy storage system may include a battery pack having a plurality of battery cells, a power converter, a pump which supplies a fluid to the battery pack or the power converter, a radiator which heat-exchanges the fluid flowing by the pump with air, a first valve which sends a fluid discharged from the pump to the power converter or the battery pack, and a second valve which sends the fluid discharged from the power converter to the battery pack or the radiator.

### CROSS-REFERENCE TO RELATED APPLICATION

This application claims priority under 35 U.S.C. § 119 to Korean Application No. 10-2021-0152588, filed in Korea on Nov. 8, 2021, whose entire disclosure is hereby incorporated by reference.

### BACKGROUND

### 1 Field

The present disclosure relates to an energy storage system, and more particularly, to an energy storage system for cooling a battery (or the like) using a fluid.

### 2. Background

Up to now, a heat dissipation of most energy storage system mainly adopts forced convection using a fan or natural convection using a heat sink. Commercial and industrial energy storage systems are adopting an air-cooling method using a fan, and a home energy storage system may be using a natural convection method. In the example of home energy storage systems, since the capacity is small compared to commercial and industrial energy storage systems, heat of a heating element can be dissipated to a heat sink. In the example of large-capacity commercial and industrial energy storage systems, an air cooling method using a fan is mainly adopted. This is because that when a fan is attached, parts that generate more heat with natural convection can be easily cooled with the fan, compared to natural convection.

U.S. Pat. No. 8,448,696 B2, the subject matter of which is incorporated herein by reference, discloses a water cooling structure for cooling a power converter and a battery pack using a four-way valve. The above document discloses the use of a four-way valve in order to use four operation modes with a single shape valve.

However, when using a four-way valve, when flows are sent in two or three directions, a large amount of flow may occur in one direction. The four-way valve has a problem in that the flow may be temporarily stopped when changing the direction and opening/closing the flow. When using a four-way valve, there is a problem in that two pumps must be used to change the direction of flow.

### BRIEF DESCRIPTION OF THE DRAWINGS

Arrangements and embodiments may be described in detail with reference to the following drawings in which like reference numerals refer to like elements and wherein:

FIG. 1 is a schematic diagram of an energy storage system according to an embodiment of the present disclosure;

FIG. 2 is a perspective view of a first valve or a second valve according to an embodiment of the present disclosure;

FIG. 3A is a cross-sectional view of one side of a control valve when fluid (or water) is supplied to a first outlet (or a first load part);

FIG. 3B is a cross-sectional view of the other side of the control valve when fluid is supplied to the first outlet;

FIG. 4A is a cross-sectional view of one side of the control valve when fluid is supplied to a second outlet (or second load part);

FIG. 4B is a cross-sectional view of the other side of the control valve when fluid is supplied to the second outlet;

FIG. 5A is a cross-sectional view of one side of the control valve when fluid is supplied to the first outlet and the second outlet;

FIG. 5B is a cross-sectional view of the other side of the control valve when fluid is supplied to the first outlet and the second outlet;

FIG. 6 is a block diagram of a controller and a configuration related thereto according to an embodiment of the present disclosure;

FIG. 7 is a schematic diagram for explaining the flow of a fluid in a simultaneous cooling mode of the energy storage system of the present disclosure;

FIG. 8 is a schematic diagram for explaining the flow of a fluid in a combined mode of the energy storage system of the present disclosure;

FIG. 9 is a schematic diagram for explaining the flow of a fluid in a battery pack cooling mode of the energy storage system of the present disclosure; and

FIG. 10 is a schematic diagram for explaining the flow of a fluid in a power converter cooling mode of the energy storage system of the present disclosure.

### DETAILED DESCRIPTION

Advantages and features of the present disclosure and methods of achieving them will become apparent with reference to the embodiments described below in detail in conjunction with the accompanying drawings. However, the present disclosure is not limited to the embodiments disclosed below, but may be implemented in various different forms, and these embodiments are provided only to allow the disclosure of the present disclosure to be complete, and to completely inform those of ordinary skill in the art to which the present disclosure belongs, the scope of the invention, and the present disclosure is only defined by the scope of the claims. Like reference numerals refer to like elements throughout.

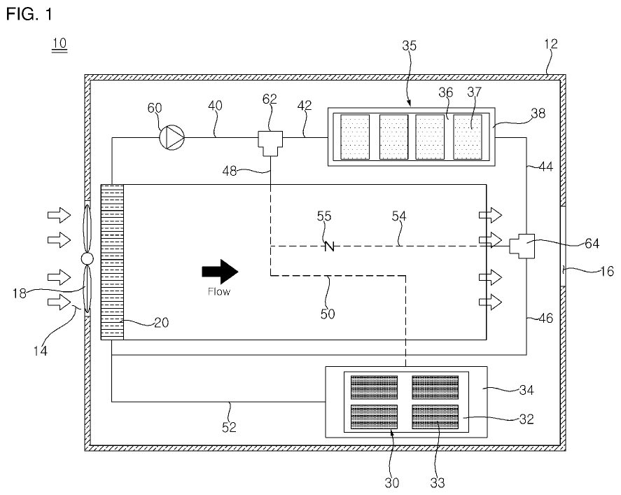

Referring to FIG. 1, an energy storage system 10 includes a case 12, a battery pack 30 which is disposed inside the case 12, and in which a plurality of battery cells are disposed, a power converter 35 (PCS) that converts characteristics of electricity so as to charge or discharge the plurality of battery cells disposed in the battery pack 30, a pump 60 for supplying a cooling fluid to the battery pack 30 or the power converter 35, a radiator 20 for cooling a cooling fluid flowing from the pump 60, a fan 18 that forms an air flow from an exterior to the radiator 20, a first valve 62 for sending the cooling fluid flowing from the pump 60 to the battery pack 30 or to the power converter 35, and a second valve 64 for sending the cooling fluid flowing from the power converter 35 to the battery pack 30 or to the radiator 20.

The energy storage system 10 may include a cooling fluid pipe (or conduit) which is disposed inside the case 12 and supplies a cooling fluid flowing by the operation of the pump 60 to the battery pack 30 or to the power converter 35.

The case 12 may include a pack storage space 12a in which the battery pack 30 is disposed, and a heat dissipation space 12b which is formed in the upper side of the pack storage space 12a, and in which the power converter 35, the pump 60, and the radiator 20 are disposed.

The case 12 has one side in which an inlet hole 14 through which external air is introduced by the fan 18, and the other side of the case 12 in which a discharge hole 16 through which the air flowing inside the case 12 is discharged to the outside by the fan 18.

The battery pack 30 is disposed in the pack storage space 12a (of the case 12). A plurality of battery cells may be connected in series or in parallel inside the battery pack 30. A plurality of battery packs 30 may be disposed inside the case 12. Each of the plurality of battery packs 30 may be connected in series with each other.

The battery pack 30 may include a plurality of battery cells 33, a pack housing 32 in which the plurality of battery cells 33 are stored, and a first cooling plate 34, which is in contact with the plurality of battery cells 33, and through which a fluid flows.

The pack housing 32 forms a space in which the plurality of battery cells 33 are disposed. The pack housing 32 may form a structure for fixing the plurality of battery cells 33 disposed therein.

The plurality of battery cells 33 may be disposed to face the same direction inside the pack housing 32.

The first cooling plate 34 may be disposed at (or in) one side of the pack housing 32 or inside the pack housing 32. The first cooling plate 34 may be disposed between the plurality of battery cells 33 disposed inside the pack housing 32. The first cooling plate 34 may absorb heat generated in the battery cell 33. The first cooling plate 34 may form a flow path through which the fluid flows therein.

The power converter 35 may include a circuit board 36, a power conversion device 37 (insulated gate bipolar transistor: IGBT) which is disposed in one side of the circuit board 36 and performs power conversion, and a second cooling plate 38 for cooling the power conversion device 37.

The power conversion device 37 may be an insulated gate bipolar transistor. Such a power conversion device may operate as an A/D converter that converts alternating current of a battery into direct current in order to operate an electronic device requiring direct current by using alternating current, and conversely, may operate as an inverter that converts direct current into alternating current in order to operate an electronic device requiring alternating current by using a storage battery.

The second cooling plate 38 may be disposed at one side of the circuit board 36 to absorb heat generated by the power converter 35. A flow path through which the fluid flows may be formed inside the second cooling plate 38.

The energy storage system 10 may include a pump discharge pipe 40 (or conduit) connecting the pump 60 and the first valve 62, a power converter inlet pipe 42 (or conduit) connecting the first valve 62 and the power converter 35, a power converter discharge pipe 44 (or conduit) connecting the power converter 35 and the second valve 64, a radiator inlet pipe 46 (or conduit) connecting the second valve 64 and the radiator 20, a first valve discharge pipe 48 (or conduit) for sending the fluid discharged from the first valve 62 to the battery pack 30, a second valve discharge pipe 54 (or conduit) for sending the fluid discharged from the second valve 64 to the battery pack 30, a battery pack inlet pipe 50 (or conduit) in which the first valve discharge pipe 48 and the second valve discharge pipe 54 are converged, and which is connected to the battery pack 30, and a battery pack discharge pipe 52 (or conduit) that connects the battery pack 30 and the radiator 20. A check valve 55 may be disposed in the second valve discharge pipe 54 to prevent the fluid from flowing backward toward the second valve 64. The battery pack inlet pipe 50 may couple to the first valve discharge pipe 48 and to the second valve discharge pipe 54.

The first valve 62 may supply (or direct) the fluid flowing from the flow pump 60 to each or both of the power converter 35 and the battery pack 30. The second valve 64 may supply the fluid flowing from the power converter 35 to the battery pack 30 or to the radiator 20. The first valve 62 may selectively provide the fluid to the first valve discharge pipe 48 or to the first valve discharge pipe 48. The second valve 64 may selectively provide the fluid to the radiator inlet pipe 46 or to the second valve discharge pipe 54.

<First valve, Second valve>

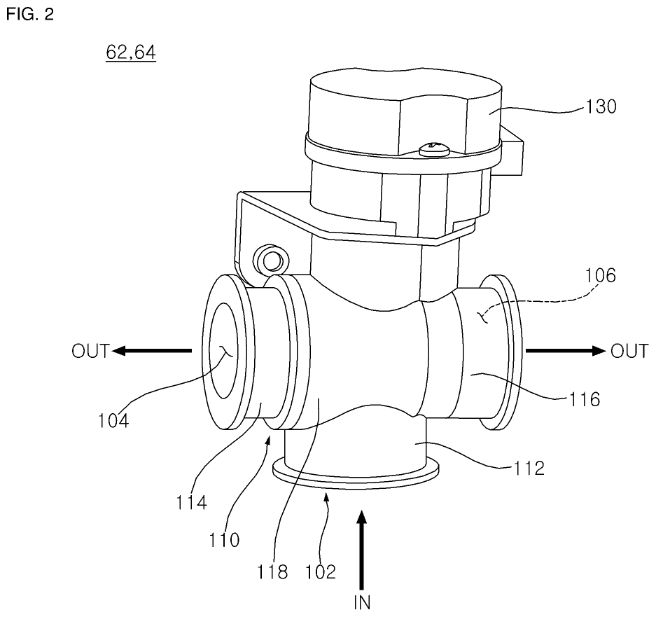

The first valve 62 and the second valve 64 according to an embodiment of the present disclosure may be described with reference to FIGS. 2 to 5B. The contents described in FIGS. 2 to 5B may be applied to both the first valve 62 and/or the second valve 64.

The first valve 62 and the second valve 64 may each separately be a three-way valve having one inlet and two outlets.

The valves 62 and 64 may include a distribution pipe 110 (or conduit) that has a flow path through which the fluid flows formed therein and has one inlet 102 and two outlets 104 and 106, a rotation valve 120 that is rotatably disposed inside the distribution pipe 110 and controls the flow direction of the fluid flowing inside the distribution pipe 110, and a valve motor 130 which is disposed at one side of the distribution pipe 110 and controls rotation of the rotation valve 120.

The distribution pipe 110 includes an inflow pipe 112 (or conduit) which has the inlet 102 and forms an inflow passage 112a therein, a first discharge pipe 114 (or conduit) which has a first outlet 104 and a first discharge passage 114a formed therein, a second discharge pipe 116 (or conduit) which has a second outlet 106 and a second discharge passage 116a formed therein, and a distribution pipe body 118 (or distribution conduit body) connecting the inflow pipe 112 to the first discharge pipe 114 and the second discharge pipe 116.

The first discharge pipe 114 and the second discharge pipe 116 are each disposed perpendicular to the inflow pipe 112. The first discharge pipe 114 and the second discharge pipe 116 extend in opposite directions with respect to the distribution pipe body 118. The first discharge pipe 114 and the second discharge pipe 116 are disposed parallel to each other. The valve motor 130 may be disposed in the opposite direction of the inflow pipe 112 with respect to the distribution pipe body 118.

Inside the distribution pipe body 118, a sharing chamber 118a may be provided for connecting the inflow passage 112a, the first discharge passage 114a, and the second discharge passage 116a. The rotation valve may be rotatably disposed in the sharing chamber 118a.

The rotation valve 120 has a valve inlet 122, which communicates with the inflow passage 112a, that is formed in the lower side, and a first valve outlet 124 and a second valve outlet 126 that are formed in a direction perpendicular to the lower side. The first valve outlet 124 and the second valve outlet 126 may be formed in a direction perpendicular to each other. Accordingly, as the rotation valve 120 rotates, the fluid flowing from the inlet 102 may be sent to the first outlet 104 or to the second outlet 106.

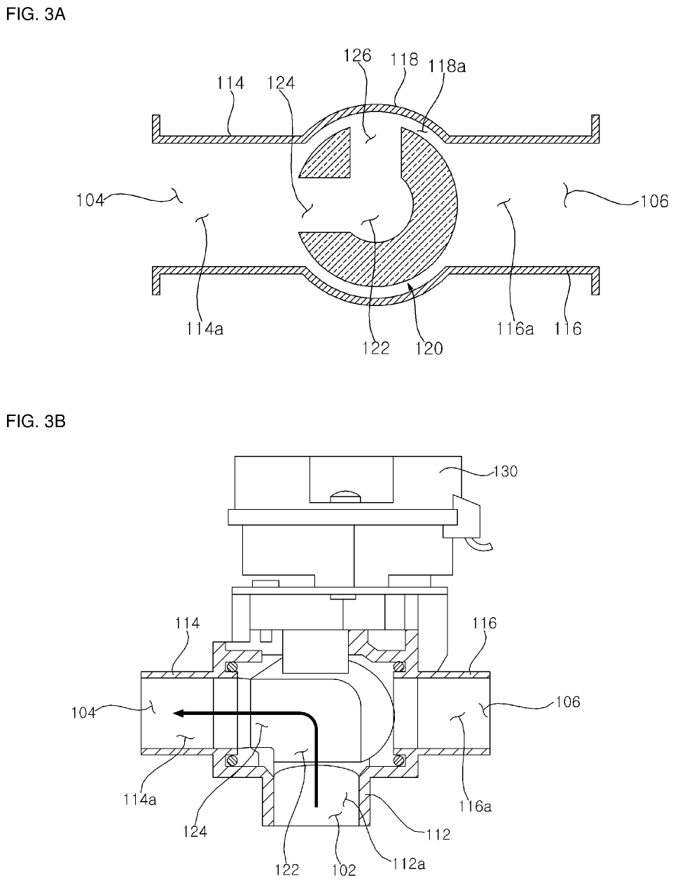

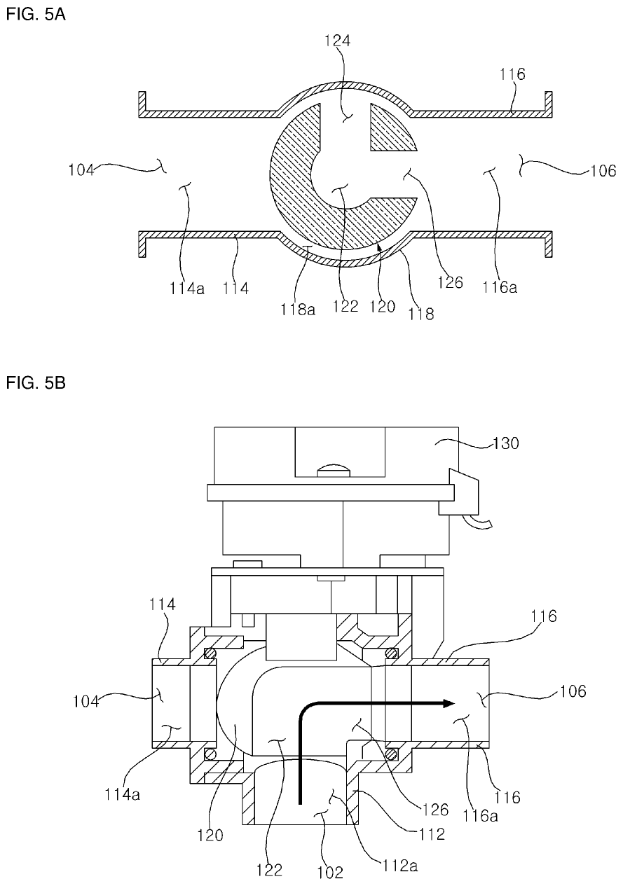

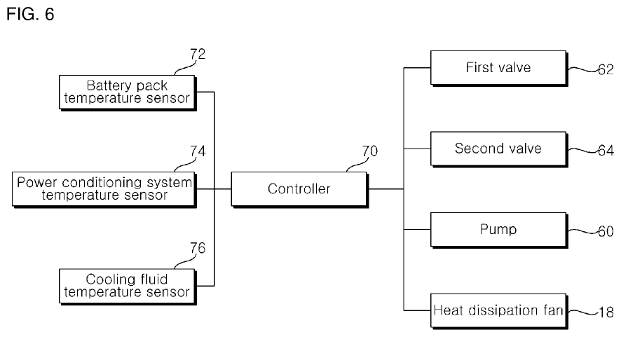

The first valve outlet 124 and the second valve outlet 126 are formed in a vertical direction. Accordingly, when the first valve outlet 124 communicates with the first discharge passage 114a as shown in FIGS. 3A and 3B, the second discharge passage 116a is blocked. Additionally, as shown in FIGS. 5A and 5B, when the second valve outlet 126 communicates with the second discharge passage 116a, the first discharge passage 114a is blocked.

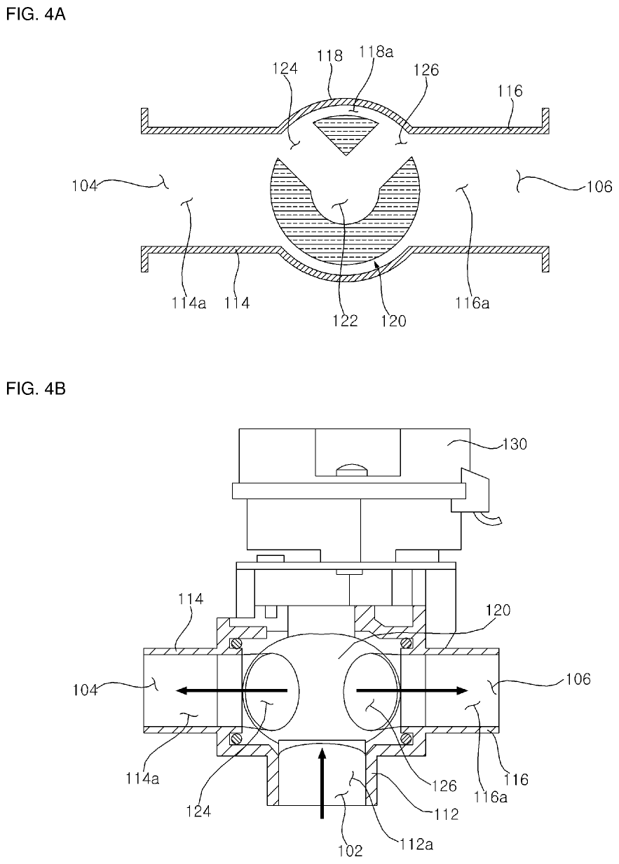

As shown in FIGS. 4A to 4B, the first valve outlet 124 may communicate with the first outlet passage 114a, and the second valve outlet 126 may be disposed to communicate with the second outlet passage 116a. However, in this example, the opening amount of the first valve outlet 124 and the opening amount of the second valve outlet 126 are reduced, so that the flow rate flowing into the first outlet passage 114a and the flow rate into the second outlet passage 116a may be reduced.

The valve motor 130 may use a DC motor. Accordingly, a rotation range of the rotation valve 120 may be adjusted by changing a pulse applied to the valve motor 130.

Referring to FIGS. 3A and 3B, when a current having a first current value is applied to the valve motor 130, the first valve outlet 124 and the first outlet passage 114a communicate with each other. The first current value may be 0 pulses, for example. When the current having a first current value is applied to the valve motor 130, the fluid introduced into the inlet 102 may flow to the first outlet 104.

In the first valve 62, when the current having a first current value is applied to the valve motor 130, the fluid flowing in from the pump 60 may be supplied (or provided) to the power converter 35. In the second valve 64, when the current having a first current value is applied to the valve motor 130, the fluid flowing in from the power converter 35 may be supplied to the radiator 20.

Referring to FIGS. 5A to 5B, when a current having a second current value is applied to the valve motor 130, the second valve outlet 126 and the second outlet passage 116a communicate with each other. The second current value may be greater than the first current value. The second current value may be 2000 pulses, for example.

When the current having a second current value is applied to the valve motor 130, the fluid introduced into the inlet 102 may flow to the second outlet 106.

In the first valve 62, when the current having a second current value is applied to the valve motor 130, the fluid flowing in from the pump 60 may be supplied (or provided) to the battery pack 30. In the second valve 64, when the current having a second current value is applied to the valve motor 130, the fluid flowing in from the power converter 35 may be supplied to the battery pack 30.

Referring to FIGS. 4A and 4B, when the current having a third current value is applied to the valve motor 130, the first valve outlet 124 and the first discharge passage 114a may communicate with each other, and the second valve outlet 126 and the second discharge passage 116a may communicate with each other. The third current value may be greater than the first current value and smaller than the second current value. The third current value may be 1000 pulses, for example.

When the current having a third current value is applied to the valve motor 130, the fluid introduced into the inlet 102 may flow to the first outlet 104 and to the second outlet 106.

In the first valve 62, when the current having a third current value is applied to the valve motor 130, the fluid flowing in from the pump 60 may be supplied (or provided) to each of the power converter 35 and the battery pack 30. In the second valve 64, when the current having a third current value is applied to the valve motor 130, the fluid flowing in from the power converter 35 may be supplied (or provided) to each of the battery pack 30 and the radiator 20.

A current having a fourth current value that is greater than the first current value and smaller than the third current value may be applied to the valve motor 130, or a current having a fifth current value that is greater than the third current value and smaller than the second current value may be applied to the valve motor 130.

When the current having a fourth current value is applied to the valve motor 130, the fluid is discharged to the first outlet 104 and to the second outlet 106. However, the amount of the fluid discharged to the first outlet 104 may be greater than the amount of the fluid discharged to the second outlet 106.

When the current having a fifth current value is applied to the valve motor 130, the fluid is discharged to the first outlet 104 and the second outlet 106. However, the amount of fluid discharged to the first outlet 104 may be smaller than the amount of the fluid discharged to the second outlet 106.

<Controller>

The energy storage system 10 may include a controller 70 for controlling operation of the pump 60, operation of the fan 18, and opening and closing of the first valve 62 and the second valve 64. The controller 70 may be a structure that includes hardware.

The energy storage system 10 may include a battery pack temperature sensor 72 for detecting the temperature of the battery pack 30, a power converter temperature sensor 74 (or power conditioning system temperature sensor) for detecting the temperature of the power converter 35, and a fluid temperature sensor 76 for detecting the temperature of the fluid discharged from the radiator 20 (or at the radiator).

The controller 70 may cool the battery pack 30 or the power converter 35 by adjusting the first valve 62 and the second valve 64 based on the temperature detected from the battery pack temperature sensor 72, the power converter temperature sensor 74, and/or the fluid temperature sensor 76. The controller 70 may adjust the first valve 62 and the second valve 64 to adjust an amount of fluid discharged from the first valve 62 or the second valve 64 based on an opening degree of the corresponding valve.

The controller 70 may adjust the rotation speed of the fan 18 or the pump 60 based on the temperature detected from the battery pack temperature sensor 72, the power converter temperature sensor 74, and/or the fluid temperature sensor 76.

<Operation>

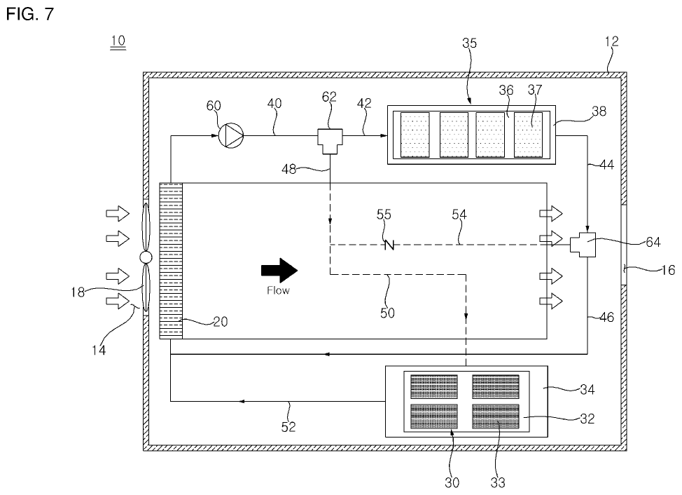

An operation of the energy storage system 10 may be described with reference to FIGS. 7 to 10.

The energy storage system 10 may be operated in a simultaneous cooling mode for simultaneously cooling the battery pack 30 and the power converter 35, a combined mode for cooling the power converter 35 and heating the battery pack 30, a battery pack cooling mode for cooling only the battery pack 30, and/or a power converter cooling mode for cooling only the power converter 35.

Referring to FIG. 7, while in the simultaneous cooling mode, the fluid cooled in the radiator 20 may flow to each of the power converter 35 and the battery pack 30. That is, the first valve 62 discharges the fluid flowing in from the pump 60 to each of the power converter 35 and the battery pack 30.

At this time, when the temperature of the fluid supplied to the first valve 62 detected from the fluid temperature sensor 76 exceeds a first set temperature, the controller 70 may increase the rotation speed of the fan 18, and/or may operate the pump 60 to increase the flow rate of the fluid discharged from the pump 60.

Additionally, the controller 70 may compare the temperature detected from the battery pack temperature sensor 72 and the temperature detected from the power converter temperature sensor 74, and adjust the first valve 62 to increase the flow rate of the fluid toward the component (i.e., the battery pack or the power converter) having a higher temperature.

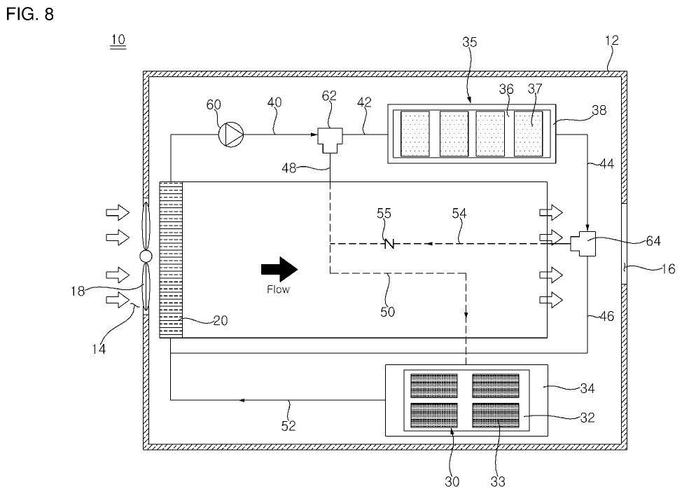

Referring to FIG. 8, in the combined mode, the fluid flowing from the pump 60 may sequentially flow to the power converter 35 and to the battery pack 30. Accordingly, the power converter 35 may be cooled by the fluid, and the fluid that has absorbed heat from the power converter 35 may be supplied (or provided) to the battery pack 30 to preheat the battery pack 30.

At this time, the controller 70 may prevent the fan 18 from rotating, so that the fluid may lose (or reduce) heat from the battery pack 30 and the fluid can receive heat from the power converter 35.

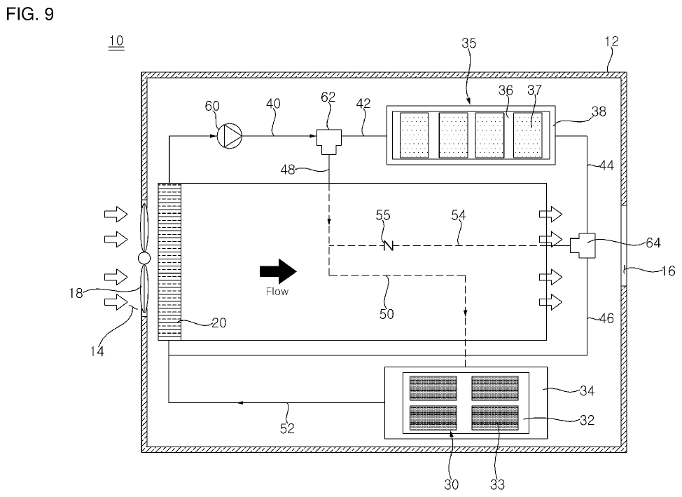

Referring to FIG. 9, while in the battery pack cooling mode, the fluid discharged from the pump 60 is supplied (or provided) only to the battery pack 30 by adjusting the first valve 62. Accordingly, the fluid flowing from the pump 60 flows to the first valve 62, the battery pack 30, and the radiator 20.

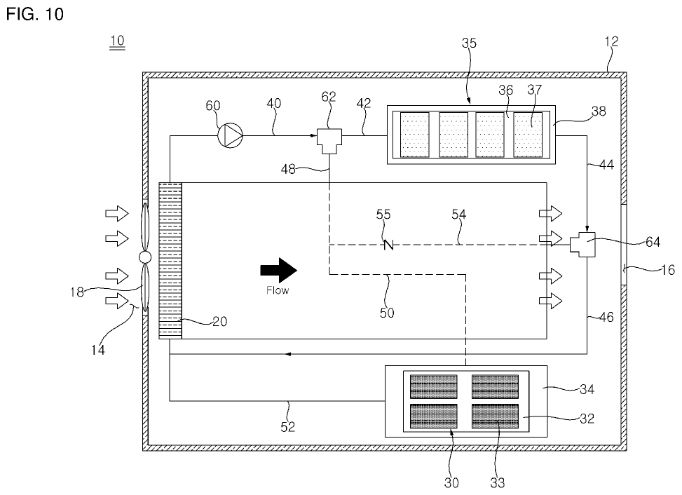

Referring to FIG. 10, while in the power converter cooling mode, the fluid flowing through the pump 60 may pass only through the power converter 35 and flow to the radiator 20 by adjusting the first valve 62 and the second valve 64.

The first valve 62 discharges the fluid flowing in from the pump 60 toward the power converter 35. The second valve 64 discharges the fluid flowing in from the power converter 35 to the radiator 20.

According to the energy storage system of the present disclosure, there are one or more of the following effects. First, it has an advantage of providing an integrated fluid that can be used in various environments and climates by using a single pump and two three-way valves. Additionally, since a single pump is used, there is an advantage that power reduction effect can be expected. Second, there is a structural advantage in that the flow drift can be prevented compared to using a four-way valve because it can be designed to use a three-way valve.

The present disclosure has been made in view of the above problems, and provides an energy storage system capable of cooling and heating a battery by using a single pump, in a structure for cooling a battery pack by water cooling.

The present disclosure further provides an energy storage system capable of adjusting a flow by a part for supplying a fluid.

In accordance with an aspect of the present disclosure, an energy storage system includes: a battery pack in which a plurality of battery cells electrically connected are disposed; a power converter which converts characteristic of electricity so as to charge or discharge the plurality of battery cells disposed in the battery pack; a pump which supplies a fluid to the battery pack or the power converter; a radiator which heat-exchanges the fluid flowing by the pump with air; a first valve which sends a fluid discharged from the pump to the power converter or the battery pack; and a second valve which sends the fluid discharged from the power converter to the battery pack or the radiator, so that various modes of operation can be performed through one pump and two valves.

The energy storage system further includes: a power converter inlet pipe which connects the first valve and the power converter; a radiator inlet pipe which sends the fluid discharged from the second valve to the radiator; a first valve discharge pipe which sends the fluid discharged from the first valve to the battery pack; a second valve discharge pipe which sends the fluid discharged from the second valve to the battery pack; and a battery pack inlet pipe in which the first valve discharge pipe and the second valve discharge pipe are converged, and which is connected to the battery pack, so that the fluid discharged from the second valve may be flowed in combination with the fluid discharged from the first valve or may be flowed separately.

A check valve is disposed in the second valve discharge pipe so as to prevent the fluid from flowing backward in a direction of the second valve.

The first valve sends the fluid flowing in from the pump to one of the power converter and the battery pack, or to each of the power converter and the battery pack, so that each of the power converter and the battery pack can be cooled individually, or the power converter and the battery pack can be cooled simultaneously.

The energy storage system further includes: a controller which controls an operation of the first valve and the second valve; a battery pack temperature sensor which detects a temperature of the battery pack; and a power converter temperature sensor which detects a temperature of the power converter, wherein the controller adjusts a flow rate of the fluid supplied to the battery pack and the power converter, based on the temperature detected by the battery pack temperature sensor and the temperature detected by the power converter temperature sensor, so that the flow rate of the fluid can be adjusted for a place where cooling is relatively more required.

The energy storage system further includes: a fluid temperature sensor which detects a temperature of the fluid discharged from the radiator; and a fan which supplies an external air to the radiator, wherein when the temperature of the fluid detected by the fluid temperature sensor exceeds a first set temperature, the controller operates the pump to increase a rotation speed of the fan and to increase the flow rate of the fluid supplied to the radiator, thereby quickly accomplishing the temperature control of the power converter or the battery pack.

In a simultaneous cooling mode for simultaneously cooling the power converter and the battery pack, the first valve discharges the fluid flowing in from the pump to each of the power converter and the battery pack, so that the battery pack and the power converter can be cooled simultaneously.

In the simultaneous cooling mode, the controller controls an operation of the pump to increase the flow rate of the fluid discharged from the pump, thereby increasing the cooling efficiency of each of the battery pack and the power converter.

In the simultaneous cooling mode, the controller compares the temperature detected from the battery pack temperature sensor and the temperature detected from the power converter temperature sensor, and adjust the first valve to increase the flow rate of the fluid toward a place having a higher temperature among the battery pack and the power converter, so that the flow rate of the fluid can be adjusted for a place where cooling is relatively more required.

In a combined mode for cooling the power converter and heating the battery pack, the controller adjusts the first valve and the second valve so that the fluid flowing by the pump sequentially flows to the power converter and the battery pack, thereby cooling the power converter and heating the battery pack.

In the combined mode, the controller adjusts the first valve so that the fluid supplied from the pump is supplied to the power converter, and adjusts the second valve so that the fluid supplied from the power converter is supplied to the battery pack.

The energy storage system further includes a fan that supplies an external air to the radiator, wherein in the combined mode, the controller stops an operation of the fan, thereby eliminating power loss in a situation where heat dissipation condition is not required.

The first valve or the second valve uses a three-way valve having one inlet and two outlets, so that one pump and two three-way valves may be provided.

Each of the first valve and the second valve includes: a distribution pipe which has a flow path, which is formed therein, through which the fluid flows and has a first outlet and a second outlet, which are opened in a different direction from the inlet, that are formed in one side; a rotation valve which is rotatably disposed inside the distribution pipe, and adjusts a flow direction of the fluid flowing inside the distribution pipe; and a valve motor which is disposed in one side of the distribution pipe, and rotates the rotation valve, wherein the fluid flowing from the inlet is transmitted to the first outlet or the second outlet, as the rotation valve rotates.

The distribution pipe includes: an inlet pipe which has the inlet, and forms an inflow passage therein; a first discharge pipe which has the first outlet and a first discharge passage formed therein, a second discharge pipe which has the second outlet and a second discharge passage formed therein, and a distribution pipe body which communicates the inflow passage with the first discharge pipe or the second discharge pipe, wherein each of the first discharge pipe and the second discharge pipe is disposed perpendicular to the inlet pipe, and the rotation valve has a valve inlet, which communicates with the inflow passage, that is formed in a lower side, and a first valve outlet and a second valve outlet that are formed in a direction perpendicular to the lower side, wherein the valve motor adjusts an opening range of each of the first valve outlet and the second valve outlet, thereby adjusting the flow rate of the fluid discharged to each outlet.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section could be termed a second element, component, region, layer or section without departing from the teachings of the present invention.

Spatially relative terms, such as “lower”, “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Any reference in this specification to “one embodiment,” “an embodiment,” “example embodiment,” etc., means that a particular feature, structure, or characteristic described in connection with the embodiment is included in at least one embodiment. The appearances of such phrases in various places in the specification are not necessarily all referring to the same embodiment. Further, when a particular feature, structure, or characteristic is described in connection with any embodiment, it is submitted that it is within the purview of one skilled in the art to affect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An energy storage system comprising:
a battery pack having a plurality of battery cells;
a power converter configured to convert electricity so as to charge or discharge the plurality of battery cells;
a pump configured to provide a fluid for the battery pack or the power converter;
a radiator configured to heat-exchange the fluid with air;
a first valve configured to receive the fluid from the pump and to selectively provide the received fluid to the power converter or to the battery pack; and
a second valve configured to receive the fluid from the power converter and to selectively provide the receive fluid to the battery pack or to the radiator.

2. The energy storage system of claim 1, comprising:
a power converter inlet conduit that connects the first valve to the power converter;
a radiator inlet conduit that guides the fluid from the second valve to the radiator;
a first valve discharge conduit that guides the fluid from the first valve to the battery pack;
a second valve discharge conduit that guides the fluid from the second valve to the battery pack; and
a battery pack inlet conduit to couple to the first valve discharge conduit and to couple to the second valve discharge conduit, and the battery pack inlet conduit is connected to the battery pack.

3. The energy storage system of claim 2, wherein a check valve is disposed at the second valve discharge conduit, and the check valve is configured to prevent the fluid from flowing backward toward the second valve.

4. The energy storage system of claim 1, wherein the first valve selectively provides the fluid flowing from the pump to one of the power converter and the battery pack, or the first valve selectively provides the fluid flowing from the pump to each of the power converter and the battery pack.

5. The energy storage system of claim 1, comprising:
a controller configured to control operation of the first valve and operation of the second valve;
a battery pack temperature sensor configured to detect a temperature of the battery pack; and
a power converter temperature sensor configured to detect a temperature of the power converter,
wherein the controller is configured to adjust a flow rate of the fluid provided to the battery pack and to adjust a flow rate of the fluid to the power converter, based on the temperature detected by the battery pack temperature sensor and the temperature detected by the power converter temperature sensor.

6. The energy storage system of claim 5, further comprising:
a fluid temperature sensor configured to detect a temperature of the fluid from the radiator; and
a fan configured to provide an external air to the radiator,
wherein when the temperature of the fluid detected by the fluid temperature sensor exceeds a first set temperature, the controller controls the fan to increase a rotation speed of the fan and controls the pump to increase the flow rate of the fluid from the pump.

7. The energy storage system of claim 5, wherein in a simultaneous cooling mode for simultaneously cooling the power converter and the battery pack, the first valve is configured to control the fluid flowing from the pump such that the fluid is provided to each of the power converter and the battery pack.

8. The energy storage system of claim 7, wherein in the simultaneous cooling mode, the controller controls the pump to increase the flow rate of the fluid from the pump.

9. The energy storage system of claim 7, wherein in the simultaneous cooling mode, the controller compares the temperature detected by the battery pack temperature sensor and the temperature detected by the power converter temperature sensor, and the controller controls the first valve to increase the flow rate of the fluid toward a component having a higher temperature among the battery pack and the power converter.

10. The energy storage system of claim 5, wherein in a combined mode for cooling the power converter and heating the battery pack, the controller controls the first valve and controls the second valve so that the fluid flowing from the pump sequentially flows to the power converter and to the battery pack.

11. The energy storage system of claim 10, wherein in the combined mode, the controller controls the first valve so that the fluid flowing from the pump is provided to the power converter, and controls the second valve so that the fluid from the power converter is provided to the battery pack.

12. The energy storage system of claim 10, comprising a fan configured to provide an external air to the radiator,
wherein in the combined mode, the controller controls the fan to stop.

13. The energy storage system of claim 1, wherein the first valve is a three-way valve having one inlet and two outlets, and the second valve is a three-way valve having one inlet and two outlets.

14. The energy storage system of claim 1, wherein each of the first valve and the second valve separately comprises:
a distribution conduit having a flow path through which the fluid flows and has a first outlet that is opened in a first direction and a second outlet that is opened in a second direction, wherein the first direction and the second direction are different from a direction of the inlet;
a rotation valve that is rotatably disposed inside the distribution conduit, and is configured to adjust a flow direction of the fluid flowing inside the distribution conduit; and
a valve motor disposed at one side of the distribution conduit, and the valve motor is configured to rotate the rotation valve,
wherein based on rotation of the rotation valve, the fluid flowing from the inlet is directed to the first outlet or the second outlet.

15. The energy storage system of claim 14, wherein the distribution conduit comprises:
an inlet conduit having the inlet, and is configured to form an inflow passage;
a first discharge conduit having the first outlet, and is configured to form a first discharge passage;
a second discharge conduit having the second outlet, and is configured to form a second discharge passage, and
a distribution conduit body configured to communicate the inflow passage with the first discharge conduit or the second discharge conduit,
wherein the first discharge conduit is disposed perpendicular to the inlet conduit, and the second discharge conduit is disposed perpendicular to the inlet, and
the rotation valve has a valve inlet, and a first valve outlet and a second valve outlet,
wherein the valve motor adjusts an opening range of each of the first valve outlet and the second valve outlet.

16. An energy storage system comprising:
a pump configured to provide a fluid;
a battery pack configured to store a plurality of battery cells;
a power converter;
a first valve configured to receive the fluid from the pump, to control an amount of the received fluid to be provided to the power converter, and to control an amount of the received fluid to be provided to the battery pack; and
a second valve configured to receive the fluid from the power converter, to control an amount of the fluid received from the power converter to be provided to the battery pack, and to control an amount of the fluid received from the power converter to be provided to the radiator.

17. The energy storage system of claim 16, comprising:
a power converter inlet conduit that connects the first valve to the power converter;
a radiator inlet conduit that guides the fluid from the second valve to the radiator;
a first valve discharge conduit that guides the fluid from the first valve to the battery pack;
a second valve discharge conduit that guides the fluid from the second valve to the battery pack; and
a battery pack inlet conduit to couple to the first valve discharge conduit and to couple to the second valve discharge conduit, and the battery pack inlet conduit is connected to the battery pack.

18. The energy storage system of claim 17, wherein a check valve is disposed at the second valve discharge conduit, and the check valve is configured to prevent the fluid from flowing backward toward the second valve.

19. The energy storage system of claim 17, wherein each of the first valve and the second valve separately comprises:
a distribution conduit having a flow path through which the fluid flows and has a first outlet that is opened in a first direction and a second outlet that is opened in a second direction, wherein the first direction and the second direction are different from a direction of an inlet;
a rotation valve that is rotatably disposed inside the distribution conduit, and is configured to adjust a flow direction of the fluid flowing inside the distribution conduit; and
a valve motor disposed at one side of the distribution conduit, and the valve motor is configured to rotate the rotation valve,
wherein based on rotation of the rotation valve, the fluid flowing from the inlet is directed to the first outlet or the second outlet.

20. The energy storage system of claim 19, wherein the distribution conduit comprises:
an inlet conduit having the inlet, and is configured to form an inflow passage;
a first discharge conduit having the first outlet, and is configured to form a first discharge passage;
a second discharge conduit having the second outlet, and is configured to form a second discharge passage, and
a distribution conduit body configured to communicate the inflow passage with the first discharge conduit or the second discharge conduit,
wherein the first discharge conduit is disposed perpendicular to the inlet conduit, and the second discharge conduit is disposed perpendicular to the inlet, and
the rotation valve has a valve inlet, and a first valve outlet and a second valve outlet,
wherein the valve motor adjusts an opening range of each of the first valve outlet and the second valve outlet.
